(19) United States
(12) Patent Application Publication
(10) Pub. No.: US 2026/0304941 A1
(43) Pub. Date: Oct. 1, 2026

(54) TUB ARCHITECTURE INTEGRATED CIRCUITS WITH DIELECTRIC WALLS HAVING LINERS AND CAPS OPTIONALLY FORMED IN A REFLOWABLE MATERIAL

(71) Applicant: Intel Corporation, Santa Clara, CA (US)

(72) Inventors: Dan Lavric, Portland, OR (US); Prahalad Parthangal, Beaverton, OR (US); Hongqian Sun, Bellevue, WA (US); Vijay Saradhi Mangu, Sunnyvale, CA (US)

(73) Assignee: Intel Corporation, Santa Clara, CA (US)

(21) Appl. No.: 19/092,786

(22) Filed: Mar. 27, 2025

(51) Int. Cl. H10D 84/85; H10D 30/00; H10D 30/01; H10D 30/43; H10D 62/10; H10D 84/01

(52) U.S. Cl. CPC H10D 84/851; H10D 30/014; H10D 30/019; H10D 30/43; H10D 30/502; H10D 62/121; H10D 84/0188; H10D 84/856

(57) ABSTRACT

Devices, integrated circuit structures, systems, and techniques are described herein related to a tub complementary field effect transistor architecture. Transistor structures each having vertically aligned nanowires are separated by dielectric walls. The dielectric walls may include dielectric liners and/or dielectric caps. The dielectric walls may be formed in a reflowable material used to embed the aligned nanowires. A gate structure is fabricated on each of the transistor structures by selectively by exposing the transistor structures using a patterned opening confined by the dielectric walls.

### BACKGROUND

Higher performance, lower cost, increased miniaturization, and greater density of integrated circuits (ICs) are ongoing goals of the electronics industry. To maintain the pace of increasing transistor performance, for example, scaling of features in ICs continues to be a driving force. Scaling to smaller and smaller features enables increased densities of functional units on the limited real estate of semiconductor chips. For example, shrinking transistor size allows for the incorporation of an increased number of memory or logic devices on a chip, lending to the fabrication of products with increased capacity.

However, the need to scale features of ICs faces difficulties. For example, current subtractive patterning techniques for fabricating gate contacts cannot deliver suitable threshold voltage (e.g., flat VT) for advanced NMOS to PMOS spacing (N-P spacing). Self-aligned additive architectures also face difficulties with undesirable wall profiles, flaring, and other difficulties that negatively impact gate processing and VT stability. It is with respect to these and other considerations that the present improvements have been needed. Such improvements may become critical as the desire to deploy ICs with increased densities and improved performance becomes more widespread.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements. In the figures:

FIG. 1 is a flow diagram illustrating exemplary methods for providing dielectric walls between adjacent transistor structures in tub gate architectures;

FIGS. 2, 3, 4, 5, 6, 7, 8, 9, 10, 11, 12, 13, 14, 15, 16, 17, 18 and 19 are cross-sectional side views of example transistor structures as particular fabrication operations of methods are performed;

FIG. 20 is a cross-sectional side view of a multi-layer integrated circuit device structure incorporating the integrated circuit structure of FIG. 19;

FIG. 21 illustrates exemplary systems employing integrated circuit structures with transistor structures separated by dielectric walls; and

FIG. 22 is a block diagram of a computing device, all arranged in accordance with at least some implementations of the present disclosure.

### DETAILED DESCRIPTION

One or more embodiments or implementations are now described with reference to the enclosed figures. While specific configurations and arrangements are discussed, it should be understood that this is done for illustrative purposes only. Persons skilled in the relevant art will recognize that other configurations and arrangements may be employed without departing from the spirit and scope of the description. It will be apparent to those skilled in the relevant art that techniques and/or arrangements described herein may also be employed in a variety of other systems and applications other than what is described herein.

Reference is made in the following detailed description to the accompanying drawings, which form a part hereof, wherein like numerals may designate like parts throughout to indicate corresponding or analogous elements. It will be appreciated that for simplicity and/or clarity of illustration, elements illustrated in the figures have not necessarily been drawn to scale. For example, the dimensions of some of the elements may be exaggerated relative to other elements for clarity. Further, it is to be understood that other embodiments may be utilized, and structural and/or logical changes may be made without departing from the scope of claimed subject matter. It should also be noted that directions and references, for example, up, down, top, bottom, over, under, and so on, may be used to facilitate the discussion of the drawings and embodiments and are not intended to restrict the application of claimed subject matter. Therefore, the following detailed description is not to be taken in a limiting sense and the scope of claimed subject matter defined by the appended claims and their equivalents.

In the following description, numerous details are set forth. However, it will be apparent to one skilled in the art, that the present invention may be practiced without these specific details. In some instances, well-known methods and devices are shown in block diagram form, rather than in detail, to avoid obscuring the present invention. Reference throughout this specification to “an embodiment” or “one embodiment” means that a particular feature, structure, function, or characteristic described in connection with the embodiment is included in at least one embodiment of the invention. Thus, the appearances of the phrase “in an embodiment” or “in one embodiment” in various places throughout this specification are not necessarily referring to the same embodiment of the invention. Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

As used in the description of the invention and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe structural relationships between components. It should be understood that these terms are not intended as synonyms for each other. Rather, in particular embodiments, “connected” may be used to indicate that two or more elements are in direct physical or electrical contact with each other. “Coupled” may be used to indicated that two or more elements are in either direct or indirect (with other intervening elements between them) physical or electrical contact with each other, and/or that the two or more elements co-operate or interact with each other (e.g., as in a cause an effect relationship, an electrical relationship, a functional relationship, etc.).

The terms “over,” “under,” “between,” “on”, and/or the like, as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features. The term immediately adjacent indicates such features are in direct contact. Furthermore, the terms “substantially,” “close,” “approximately,” “near,” and “about,” generally refer to being within +/-10% of a target value. The term layer as used herein may include a single material or multiple materials. As used in throughout this description, and in the claims, a list of items joined by the term “at least one of” or “one or more of” can mean any combination of the listed terms. For example, the phrase “at least one of A, B or C” can mean A; B; C; A and B; A and C; B and C; or A, B and C. The terms “lateral”, “laterally adjacent” and similar terms indicate two or more components are aligned along a plane orthogonal to a vertical direction of an overall structure.

Devices, integrated circuit die structures, apparatuses, systems, and techniques are described herein related to dielectric walls formed between gate stacks of gate all around transistor structures. The dielectric walls provide for self-aligned selective removal of sacrificial gates for processing the exposed transistor structures.

As discussed, current subtractive patterning techniques for fabricating gate contacts face difficulties including unsuitable threshold voltages across dies or wafers due to lithographic alignment while selective processing gates of the transistor structures. For example, edge placement error (EPE) misalignment during gate processing leads to undesirable VT variability in the resultant transistors. Current self-aligned additive techniques also face difficulties with undesirable wall profiles, flaring, and other difficulties that negatively impact gate processing and VT stability. In embodiments discussed herein, adjacent FET (field effect transistor) structures each include a stack of vertically aligned nanowires or channel material layers. Adjacent FET structures may be of different polarities (i.e., conductivity types: P-type or N-type) and/or they may be dedicated for different applications such as ultra-low VT (ULVT), low VT (LVT), standard VT (SVT), and high VT (HVT), and so on. For example, adjacent transistor structures may be P-LVT, P-SVT, P-HVT, N-LVT, N-SVT, N-HVT, or the like, with boundaries between the same conductivity type being characterized as N-N or P-P boundaries and boundaries between different conductivity types being characterized as N-P boundaries.

Herein, the laterally adjacent transistor structures are separated by dielectric walls (which may be characterized as pixel walls) that extend vertically across the stacks of nanowires or channel material layers. Such dielectric wall structures may form tub architectures or tub gate architectures. The dielectric walls may be embedded in sacrificial material (e.g., a sacrificial tungsten or other material). During access of particular ones of the transistor structures, a hardmask material is formed with an opening over the particular transistor structure. Ideally, the opening is perfectly aligned with the particular transistor structure; however, in real world processing, when the opening is not perfectly aligned, the dielectric walls provide EPE latitude such that the opening need only be within a portion of the dielectric material bounded by the dielectric walls. Therefore, the dielectric walls provide for a self-alignment structure for improved device performance and reduced VT variability.

Notably, the dielectric wall structures may be formed in a reflowable material for improved vertical profiles and other advantages as compared to forming the dielectric wall structures in other sacrificial materials such as tungsten. In addition or in the alternative, the dielectric wall structures include a dielectric fill that may be within dielectric liner and/or under a dielectric cap. The dielectric liner and/or dielectric cap offer advantages such as improved effective capacitance (Ceff), burying any seams in the dielectric fill, and improved structural integrity, which can all improves transistor performance. In the context of the transistor structures, the selectively exposed transistor structures may be processed using any suitable technique or techniques known in the art. For example, the exposed stacks of nanowires or channel material layers may be fabricated with the same or different dielectric or dipole material layers, the same or different work function metals, the same or different gate fill metals, and so on.

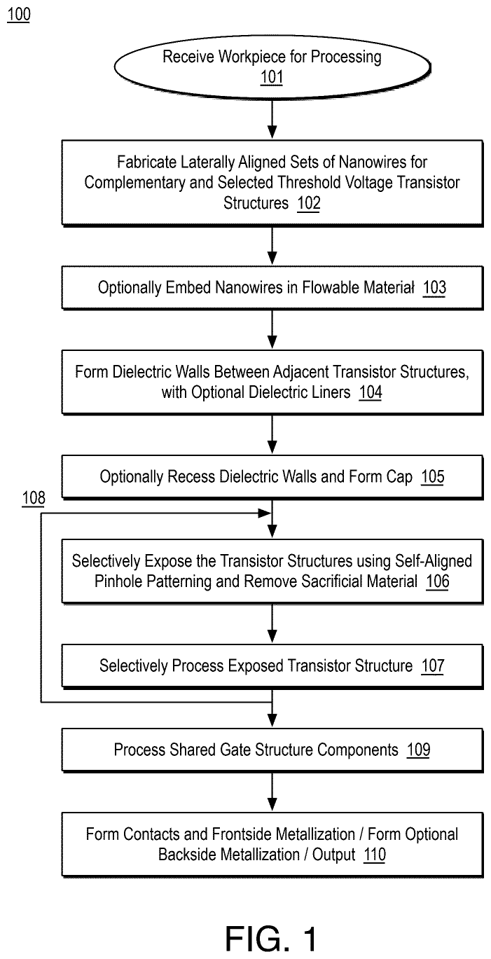

FIG. 1 is a flow diagram illustrating exemplary methods 100 for providing dielectric walls between adjacent transistor structures in tub gate architectures, arranged in accordance with at least some implementations of the present disclosure. For example, methods 100 may be implemented to fabricate any integrated circuit structures discussed herein. In the illustrated implementation, methods 100 may include one or more operations as illustrated by operations 101-110. However, embodiments herein may include additional operations, certain operations being omitted, or operations being performed out of the order provided.

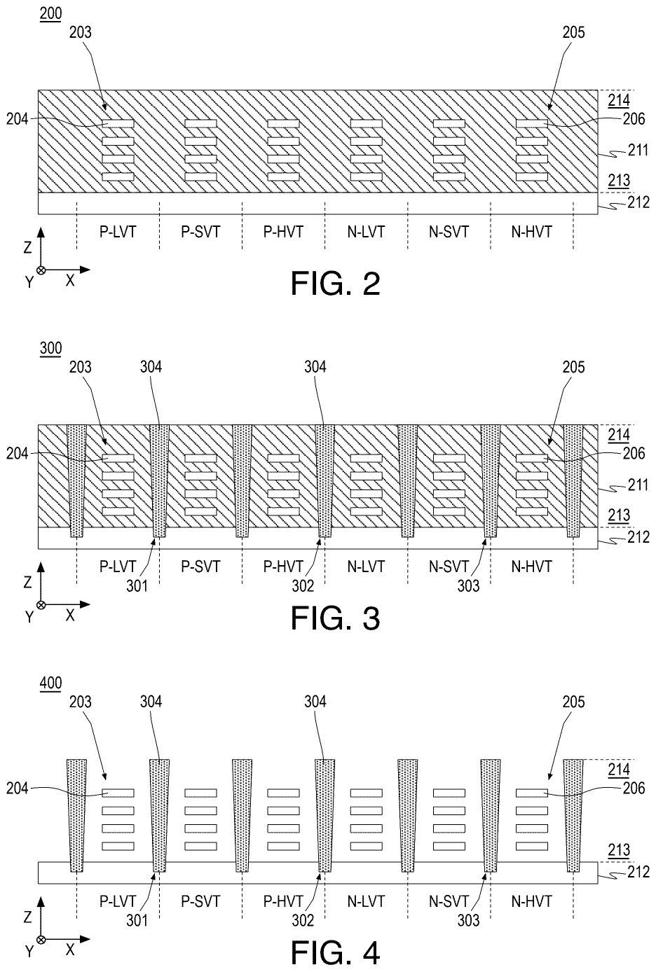

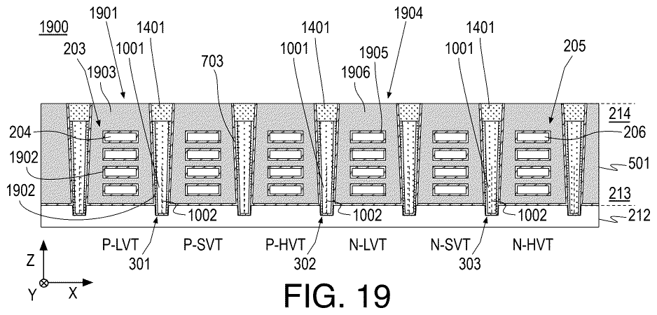

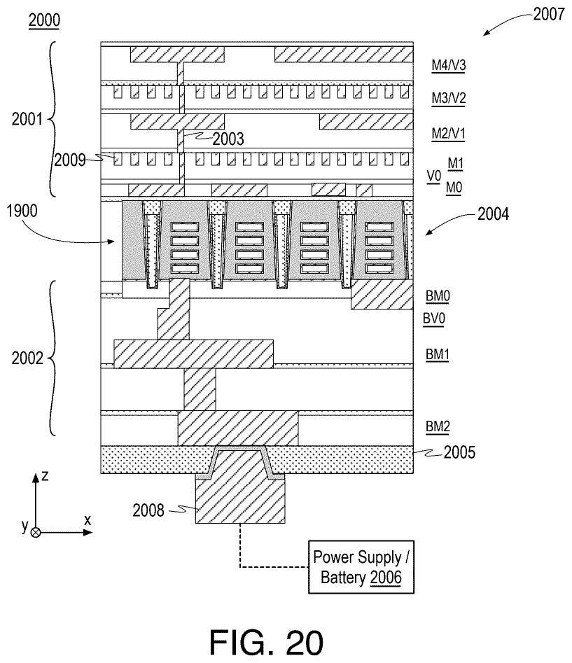

FIGS. 2, 3, 4, 5, 6, 7, 8, 9, 10, 11, 12, 13, 14, 15, 16, 17, 18 and 19 are cross-sectional side views of example transistor structures as particular fabrication operations of methods 100 are performed, arranged in accordance with at least some implementations of the present disclosure. FIG. 20 is a cross-sectional side view of a multi-layer integrated circuit device structure incorporating the integrated circuit structure of FIG. 19, arranged in accordance with at least some implementations of the present disclosure.

Processing begins at operation 101, where a workpiece such as a substrate is received for processing. The substrate may include any suitable substrate as discussed herein such as a silicon wafer or the like. In some embodiments, the substrate includes underlying devices or electrical interconnects. Processing continues at operation 102, where vertically aligned sets or stacks of complementary nanowires or channel material layers are fabricated such that laterally aligned and adjacent stacks are formed for different conductivity types (i.e., complementary NMOS and PMOS devices) and/or for different threshold voltage transistor structures.

For example, each transistor structure includes a first set of vertically aligned and separated nanowires. A second, laterally adjacent transistor structure includes a second set of vertically aligned and separated nanowires. The first set and the second set of nanowires or channel material layers may be complementary such that one set is to use a first polarity or conductivity type (i.e., n-type conductors) and the other set is to use a second polarity or conductivity type (i.e., p-type conductors). In addition or in the alternative, the first set and the second set of nanowires or channel material layers may be operable at different threshold voltages. The first and second sets may be the same materials, or they may be different.

Adjacent transistor structures (each having vertically aligned sets of nanowires) are to be laterally separate for operation. Each transistor structure is to be separated by a vertical dielectric wall as discussed further herein, and each transistor structure may be defined in a tub or tub gate architecture.

The discussed nanowires may be formed using any suitable technique or techniques. In some embodiments, alternating layers of semiconductor material layers and sacrificial layers are formed over the workpiece or substrate, the alternating (or interleaved) layers of semiconductor material layers and sacrificial layers are patterned to form fin structures of the interleaved stack of semiconductor material layers and sacrificial layers, and dummy gate and spacer structures are formed. Components of the transistor structures such as sources and drains, spacers, etc. may then be formed and the semiconductor material layers may be released, as is known in the art.

The alternating layers of semiconductor material layers and sacrificial layers may be formed using any suitable technique or techniques such as epitaxial growth techniques, deposition techniques or the like. The alternating layers of semiconductor material layers and sacrificial layers may be patterned into any number of fins using any suitable technique or techniques such as lithography and etch techniques. In some embodiments, the patterning includes one or more etches such to define the fin critical dimensions of the semiconductor material layers, and the formation of dummy gate and spacer structures. After patterning, the resultant semiconductor structures or nanoribbons are defined for use in a transistor structure. In some embodiments, the semiconductor material layers are silicon such as substantially monocrystalline silicon and the sacrificial layers are silicon germanium such as substantially monocrystalline silicon germanium.

Processing continues at operation 103, where the nanowires and any other exposed structures may be embedded in a flowable material. The reflowable material may be formed using any suitable technique or techniques such as deposition of a self-planarizing reflowable material at an elevated temperature. For example, the reflowable material may be self-planarizing high temperature (e.g., 450-500° C.) nitrogen curable film or layer. In some embodiments, the reflowable material is an amorphous carbon layer or film (e.g., the reflowable material includes carbon). In some embodiments, the reflowable material is an amorphous silicon layer or film (e.g., the reflowable material includes silcon). In some embodiments, the reflowable material is a reflowable silicon oxide layer or film (e.g., the reflowable material includes silicon and oxygen). In some embodiments, the reflowable material is a reflowable silicon oxycarbide layer or film (e.g., the reflowable material includes carbon, silicon, and oxygen). In some embodiments, reflowable material 211 is a reflowable aluminum oxide layer or film (e.g., the reflowable material includes aluminum and oxygen).

FIG. 2 is a cross-sectional side view of an example integrated circuit structure 200 taken at a fin cut of transistor structures. As shown, each transistor structure (i.e., P-LVT, P-SVT, P-HVT, N-LVT, N-SVT, N-HVT) includes a stack of vertically aligned nanowires or channel material layers as labeled with respect to stack 203 of vertically aligned nanowires or channel material layers 204 and stack 205 of vertically aligned nanowires or channel material layers 206. Herein, only particular components are labeled for the sake of clarity of presentation. As is shown, each of channel material layers 204 of stack 203 is laterally aligned with corresponding ones of channel material layers 206 of stack 205. Herein, the vertical or z-direction is orthogonal to an underlying substrate and in a build-up direction as is typical in the art. The horizontal or lateral direction is orthogonal to the vertical z-direction.

Furthermore, in the context of integrated circuit structure 200, each transistor structure includes source and drain structures that are into and out of the page with respect to the view shown herein. Such source and drain structures may be formed using any suitable technique or techniques such as epitaxial growth techniques, as is known in the art. The source and drain structures may include epitaxial nucleation layers and a bulk epitaxial material, with the source and drain structures being doped for the pertinent conductivity type. Exemplary source and drain materials include boron and/or gallium doped epitaxial silicon and germanium (SiGe) for p-type transistor structures and phosphorous and/or arsenic doped epitaxial silicon for n-type transistor structures. In some embodiments, the source and drain structures are fabricated prior to release of channel material layers 204, 206.

Integrated circuit structure 200 may include a bottom gate layer 212, and channel material layers 204, 206 may be embedded in a reflowable material 211. Notably, reflowable material 211 offers advantages with respect to other sacrificial materials such as sacrificial tungsten. Reflowable material 211 may include any suitable reflowable material such as a reflowable, self-planarizing and high temperature (e.g., 450-500° C.) nitrogen curable amorphous carbon film (ACF) hard mask material. In some embodiments, reflowable material 211 is an amorphous carbon layer or film. In some embodiments, reflowable material 211 is an amorphous silicon layer or film. In some embodiments, reflowable material 211 is a reflowable silicon oxide layer or film. In some embodiments, reflowable material 211 is a reflowable silicon oxycarbide layer or film. In some embodiments, reflowable material 211 is a reflowable aluminum oxide layer or film.

Bottom gate layer 212 has a top surface that defines a gate bottom 213, while a top surface of reflowable material 211 (and subsequently formed gate stacks or structures) defines a gate top 214. Bottom gate layer 212 may be any suitable material and, in some embodiments, is the material of an underlying substrate. For example, the underlying substrate and/or bottom gate layer 212 may be or include a Group IV material (e.g., silicon), such as a substantially monocrystalline material.

Returning to FIG. 1, processing continues at operation 104, where a dielectric wall is formed between the laterally adjacent transistor structures, with the transistor structures embedded in the reflowable sacrificial material. The dielectric walls between the transistor structures may be formed using any suitable technique or techniques. In some embodiments, a mask is patterned over the reflowable sacrificial material such that openings in the mask define the pattern of the dielectric walls. Openings for the dielectric walls may then be etched and the mask removed. The openings may be filled with dielectric material using any suitable technique or techniques such as chemical vapor deposition (CVD), thermal oxidization, or others. Any overfill or overburden may be removed using planarization techniques. In other embodiments, formation of the dielectric wall includes fabrication of a dielectric liner and/or a dielectric cap, as discussed further herein below.

FIG. 3 is a cross-sectional side view of an example integrated circuit structure 300 similar to integrated circuit structure 200, after formation of dielectric walls 301, 302, 303 of dielectric fill material 304. As discussed, dielectric walls 301, 302, 303 may be formed using any suitable technique or techniques such as patterning a mask over reflowable material 211 with openings defining dielectric walls 301, 302, 303, etching the openings, and filling the openings with dielectric fill material 304 to form dielectric walls 301, 302, 303, with any overburden being removed using planarization techniques. Dielectric fill material 304 of dielectric walls 301, 302, 303 may be any suitable material or materials including silicon oxide, silicon nitride, silicon oxynitride, silicon carbide, or silicon oxycarbide. For example, dielectric fill material 304 of dielectric walls 301, 302, 303 may include silicon and one or more of oxygen, nitrogen, and carbon. In the following, examples of dielectric walls 301, 302, 303 having one or both of a liner enclosing dielectric fill material 304 and/or a cap covering dielectric fill material 304 are discussed. It is noted that such structures may be formed using reflowable material 211 or another sacrificial material such as sacrificial tungsten. For example, the use of reflowable material 211, a liner, and a cap are not mutually exclusive but instead may be combined in any combination and any characteristics discussed with respect to dielectric walls 301, 302, 303 having only dielectric fill material 304 may be applied to any dielectric walls 301, 302, 303 herein. Dielectric wall 301 is an example of a dielectric wall between transistor structures of the same conductivity type but different threshold voltages for p-type transistor structures (i.e., a P-P boundary), dielectric wall 303 is an example of a dielectric wall between transistor structures of the same conductivity type but different threshold voltages for n-type transistor structures (i.e., an N-N boundary), and dielectric wall 302 is an example of a dielectric wall is between transistor structures different conductivity types (i.e., an N-P boundary).

Dielectric walls 301, 302, 303 extend into and out of the page (i.e., in the y-dimension) and, with bottom gate layer 212, define tubs or wells for each transistor structure. As shown, dielectric walls 301, 302, 303 are high aspect ratio structures due, in part to the vertical nature of stacks 203, 205. As discussed below, when removing pertinent portions of reflowable material 211 (or other sacrificial material) for selectively processing transistor structures, dielectric walls 301, 302, 303 provide self-alignment structures. Notably, in the absence of dielectric walls 301, 302, 303 selective removal of reflowable material 211 (or other sacrificial material) has difficulties in alignment with the underlying transistor structures. Inclusion of dielectric walls 301, 302, 303 resolves these issues and offers other advantages.

FIG. 4 is a cross-sectional side view of an example integrated circuit structure 400 similar to integrated circuit structure 300, after optional removal of reflowable material 211. In some embodiments, reflowable material 211 may be removed to simultaneously process transistor structures and/or to provide a more suitable sacrificial gate material for later processing. Reflowable material 211 may be removed using any suitable technique or techniques such as patterning and etch techniques.

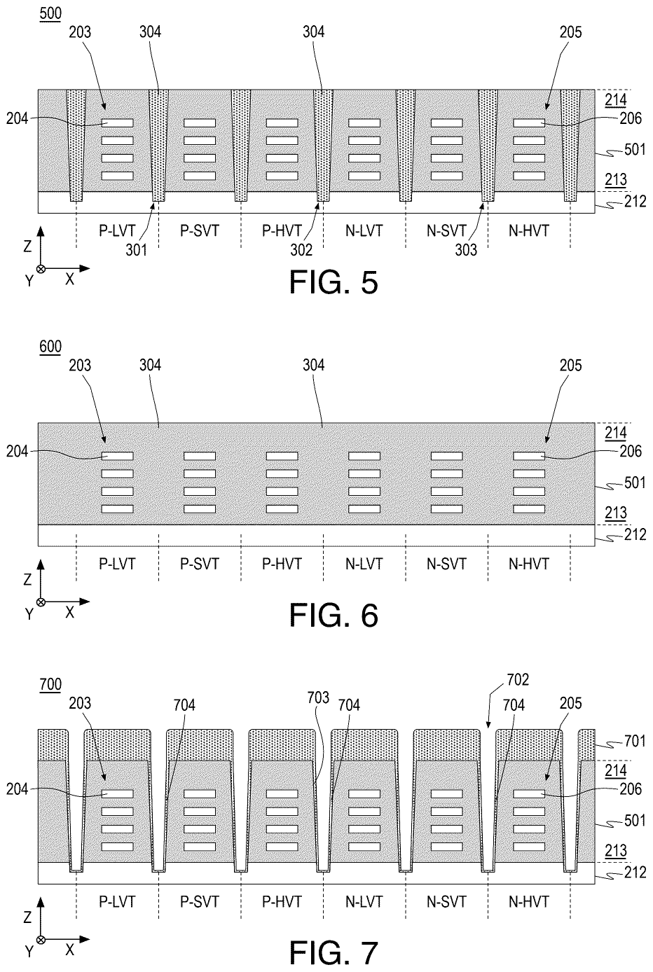

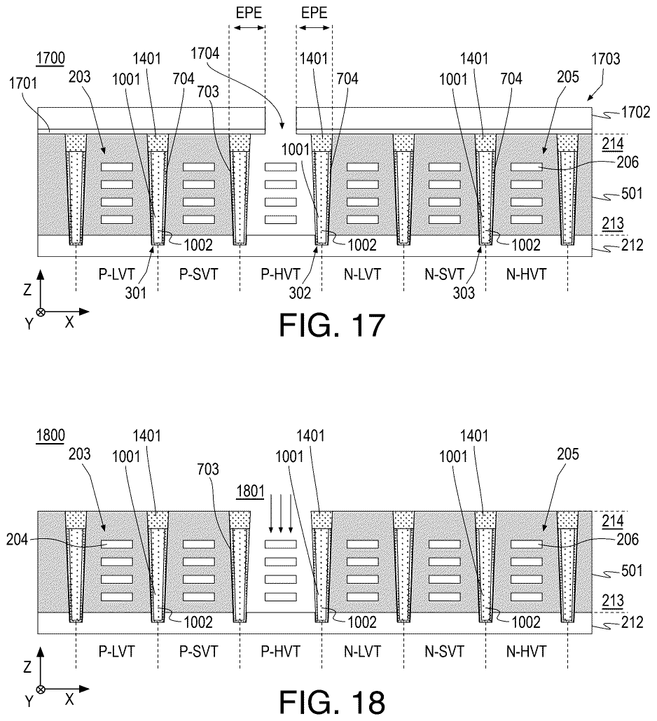

FIG. 5 is a cross-sectional side view of an example integrated circuit structure 500 similar to integrated circuit structure 400, after formation of sacrificial gate material 501. Sacrificial gate material 501 may be formed using any suitable technique or techniques such as bulk deposition followed by planarization processing. In some embodiments, sacrificial gate material 501 is tungsten, however other material such as hardmask materials may be used. It is noted that the processing discussed with respect to FIGS. 4 and 5 may be bypassed in some process flows. Furthermore, integrated circuit structure 500 may be used for selective transistor structure processing as discussed with respect to FIGS. 17 to 20. Notably, although illustrated with respect to integrated circuit structure 1400 as a starting point, such processing as discussed with respect to FIGS. 17 to 20 may be performed with any of integrated circuit structures 300, 500, 900, 1100, 1600 or others discussed herein.

As discussed with respect to operation 104, in some embodiments, formation of the dielectric wall includes fabrication of a dielectric liner and/or a dielectric cap. Discussion now turns to exemplary techniques for formation of a dielectric liner and/or a dielectric cap of dielectric walls 301, 302, 303 as discussed further herein below. It is noted such processing may be performed using sacrificial gate material 501 to embed underlying structures (as shown) or with reflowable material 211 embedding underlying structures.

FIG. 6 is a cross-sectional side view of an example integrated circuit structure 600 similar to integrated circuit structure 200, but with each transistor structure (i.e., P-LVT, P-SVT, P-HVT, N-LVT, N-SVT, N-HVT) embedded in sacrificial gate material 501. Sacrificial gate material 501may include any suitable material that may be removed and replaced by a gate stack or gate structure, as discussed herein. In some embodiments, sacrificial gate material 501is tungsten, however other material such as hardmask materials or those discussed with respect to reflowable material 211may be used.

FIG. 7 is a cross-sectional side view of an example integrated circuit structure 700 similar to integrated circuit structure 600, after formation of dielectric liners 704 and patterned dielectric layer 701. Dielectric liners 704 and patterned dielectric layer 701 may be any suitable material or materials. In some embodiments, dielectric liners 704 and patterned dielectric layer 701 are or include silicon nitride (i.e., dielectric liners 704 and patterned dielectric layer 701 include silicon and nitrogen). In some embodiments, dielectric liners 704 and patterned dielectric layer 701 are or include silicon carbide (i.e., dielectric liners 704 and patterned dielectric layer 701 include silicon and carbon). Other materials may be used.

Dielectric liners 704 and patterned dielectric layer 701 may be formed using any suitable technique or techniques. In some embodiments, sacrificial gate material 501 is patterned to form openings 702 using patterning and etch techniques. Dielectric liners 704 and patterned dielectric layer 701 may then be formed using deposition techniques. In some embodiments, patterned dielectric layer 701 is part of a hard mask patterning layer used to form openings 702, and dielectric liners 704 are subsequently formed. Notably, dielectric liners 704 are on sidewalls 703 of sacrificial gate material 501.

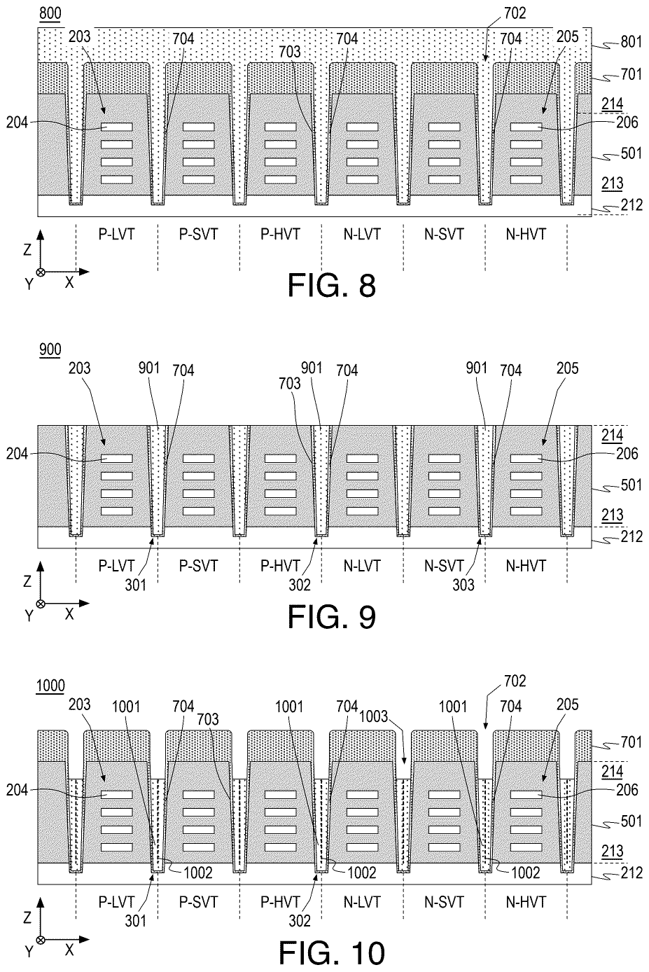

FIG. 8 is a cross-sectional side view of an example integrated circuit structure 800 similar to integrated circuit structure 700, after formation of bulk dielectric material 801. Bulk dielectric material 801 may be any suitable material or materials. In some embodiments, bulk dielectric material 801 is or includes silicon oxide (i.e., bulk dielectric material 801 includes silicon and oxygen). In some embodiments, bulk dielectric material 801 is or includes silicon oxyfluoride (i.e., bulk dielectric material 801 includes silicon, oxygen, and fluorine). In some embodiments, bulk dielectric material 801 includes aluminum oxide, hafnium oxide, zirconium oxide, titanium silicon oxide, or hafnium silicon oxide. For example, bulk dielectric material 801 may include aluminum and oxygen; hafnium and oxygen; zirconium and oxygen; titanium, silicon, and oxygen; or hafnium, silicon, and oxygen; or silicon and nitrogen. Bulk dielectric material 801 may be formed using any suitable technique or techniques such as material deposition techniques inclusive of atomic layer deposition (ALD), plasma enhanced chemical vapor deposition (PECVD), chemical vapor deposition (CVD), or the like.

FIG. 9 is a cross-sectional side view of an example integrated circuit structure 900 similar to integrated circuit structure 800, after planarization processing to remove patterned dielectric layer 701, leaving dielectric walls 301, 302, 303 including dielectric liners 704 and fill dielectric material 901, which may have any characteristics discussed with respect to bulk dielectric material 801. Integrated circuit structure 900 illustrates an example where dielectric walls 301, 302, 303 have dielectric liners 704 and fill dielectric material 901 but are absent any cap. In some embodiments, integrated circuit structure 900 may be used for selective transistor structure processing as discussed with respect to FIGS. 17 to 20.

In some embodiments, with reference to FIG. 8, fabrication of bulk dielectric material 801 can form seams within openings 702 due to bulk dielectric material 801 being deposited on sidewalls within openings 702 that merges to a seam. As used herein, the term seam indicates a discontinuity or gap between two bulk material portions. Notably, any seam within openings 702 can cause difficulties in subsequent processing due to the seam being susceptible to being filled with metal (thereby reducing the insulating properties of dielectric walls 301, 302, 303 and possibly causing shorts), due to causing a lack of structural integrity, and other issues. Discussion now turns to fabrication of a dielectric cap of dielectric walls 301, 302, 303 that is formed on bulk dielectric material 801. The dielectric cap may bury any seams and provide for increased structure integrity and other advantages. It is noted the dielectric cap may be formed with buried seams or in the absence of any seams within openings 702.

FIG. 10 is a cross-sectional side view of an example integrated circuit structure 1000 similar to integrated circuit structure 800, after recessing dielectric layer 701 to form fill dielectric material 1001 and recesses 1003 above fill dielectric material 1001. Fill dielectric material 1001 may have any characteristics discussed with respect to bulk dielectric material 801. Dielectric layer 701 may be recessed using any suitable technique or techniques such as dry etch techniques. In the context of integrated circuit structure 1000, seams 1002 are evident in fill dielectric material 1001. As discussed, seams 1002 may be formed by different fronts of material growth merging and seams 1002 may include any material discontinuity or gap within fill dielectric material 1001.

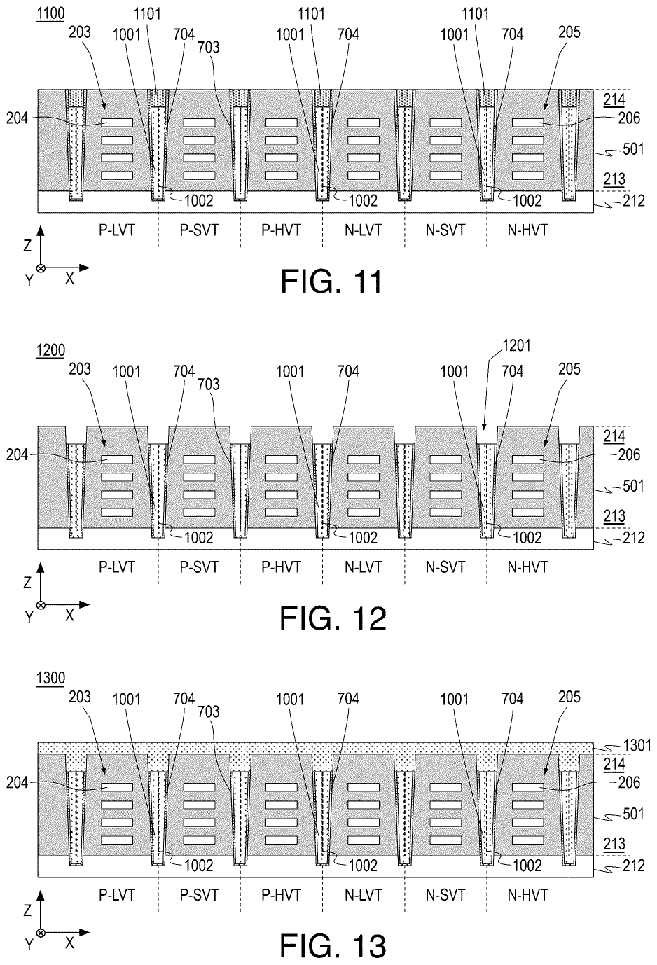

FIG. 11 is a cross-sectional side view of an example integrated circuit structure 1100 similar to integrated circuit structure 1000, after formation of a dielectric cap 1101 as part of dielectric walls 301, 302, 303. Dielectric cap 1101 may be any suitable material or materials. In some embodiments, dielectric cap 1101 is or includes silicon oxycarbide (i.e., dielectric cap 1101 includes silicon, oxygen, and carbon). In some embodiments, dielectric cap 1101 is or includes silicon nitride (i.e., dielectric cap 1101 includes silicon and nitrogen). In some embodiments, dielectric cap 1101 is or includes silicon carbide (i.e., dielectric cap 1101 includes silicon and carbon). Other material systems may be used. Dielectric cap 1101 may be formed using any suitable technique or techniques. In some embodiments, a bulk material of dielectric cap 1101 is formed and the bulk material is planarized.

Integrated circuit structure 1100 illustrates an example where dielectric walls 301, 302, 303 have dielectric cap 1101 with dielectric liners 704 and fill dielectric material 1001, such that dielectric liners 704 extend along an entire vertical length of dielectric walls 301, 302, 303 and dielectric cap 1101 is within dielectric liners 704. In some embodiments, integrated circuit structure 1100 may be used for selective transistor structure processing as discussed with respect to FIGS. 17 to 20.

FIG. 12 is a cross-sectional side view of an example integrated circuit structure 1200 similar to integrated circuit structure 1100, after removal of dielectric cap 1101 and portions of dielectric liners 704 to form recesses 1201. Recesses 1201 may be formed using any suitable technique or techniques such as timed etch processing or the like.

FIG. 13 is a cross-sectional side view of an example integrated circuit structure 1300 similar to integrated circuit structure 1200, after formation of bulk dielectric material 1301. Bulk dielectric material 1301 may be any suitable material or materials. In some embodiments, bulk dielectric material 1301 is or includes silicon oxycarbide (i.e., bulk dielectric material 1301 includes silicon, oxygen, and carbon). In some embodiments bulk dielectric material 1301 is or includes silicon nitride (i.e., bulk dielectric material 1301 includes silicon and nitrogen). In some embodiments, bulk dielectric material 1301 is or includes silicon carbide (i.e., bulk dielectric material 1301 includes silicon and carbon). Bulk dielectric material 1301 may be formed using any suitable technique or techniques such as ALD, PECVD, CVD, or the like.

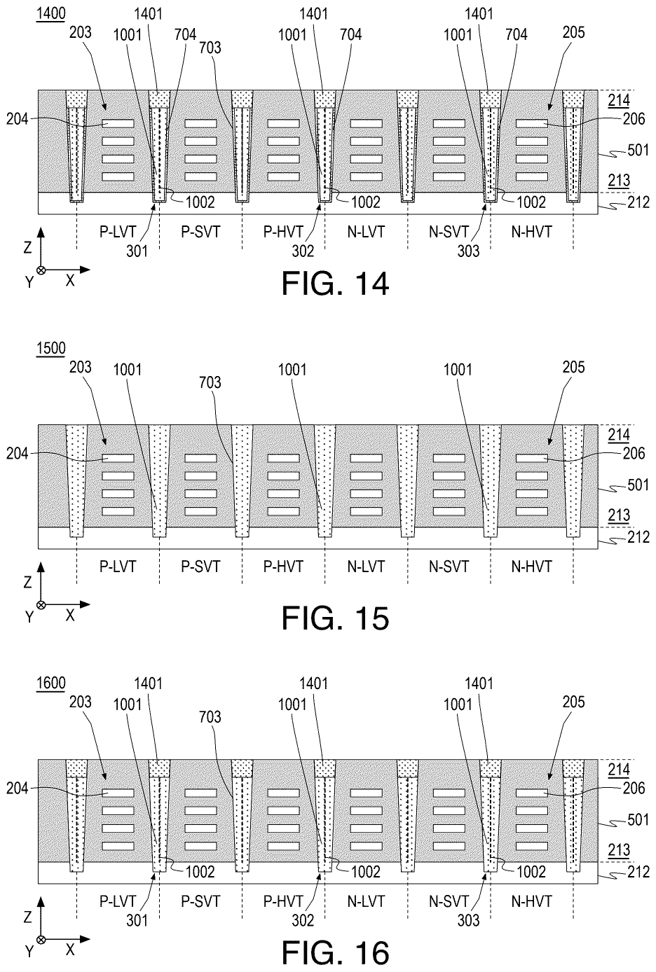

FIG. 14 is a cross-sectional side view of an example integrated circuit structure 1400 similar to integrated circuit structure 1300, after planarization processing to remove portions of bulk dielectric material 1301 to form dielectric cap 1401, which may be any material discussed with respect to bulk dielectric material 1301. Integrated circuit structure 1400 illustrates an example where dielectric walls 301, 302, 303 have dielectric cap 1401 with dielectric liners 704 and fill dielectric material 1001, such that dielectric liners 704 extend only partially along a vertical length of dielectric walls 301, 302, 303 and where dielectric cap 1401 and dielectric liners 704 define sidewall 703 of dielectric walls 301, 302, 303. In some embodiments, integrated circuit structure 1400 may be used for selective transistor structure processing as discussed with respect to FIGS. 17 to 20.

As discussed, dielectric walls 301, 302, 303 may include dielectric liners 704 and dielectric caps 1101 or dielectric caps 1401. In other embodiments, dielectric walls 301, 302, 303 may be deployed absent dielectric liners 704. Discussion now turns to fabrication of dielectric walls 301, 302, 303 without dielectric liners.

FIG. 15 is a cross-sectional side view of an example integrated circuit structure 1500 similar to integrated circuit structure 500, where fill dielectric material 1001 has been formed in sacrificial gate material 501. In alternative embodiments, reflowable material 211 may be deployed in place of sacrificial gate material 501. Integrated circuit structure 1500 may be formed using any suitable technique or techniques. In some embodiments, openings defining dielectric walls 301, 302, 303 are formed in sacrificial gate material 501 using patterning and etch techniques. Fill dielectric material 1001 may then be formed by depositing a bulk material followed by planarization techniques. As discussed, fill dielectric material 1001 may be or include, for example, silicon oxide, silicon oxyfluoride, aluminum oxide, hafnium oxide, zirconium oxide, titanium silicon oxide, hafnium silicon oxide, or other insulating material. In some embodiments, fill dielectric material 1001 is or includes silicon nitride.

FIG. 16 is a cross-sectional side view of an example integrated circuit structure 1600 similar to integrated circuit structure 1500, after formation of dielectric caps 1401. Dielectric caps 1401 may be fabricated as discussed with respect to FIGS. 13 and 14 above. For example, a bulk dielectric material may be applied using deposition techniques and planarization processing may be performed to remove overburden, leaving dielectric caps 1401. Dielectric caps 1401 may include any material discussed above such as silicon oxycarbide, silicon nitride, or silicon carbide.

As discussed, any suitable integrated circuit structure such as integrated circuit structures 300, 500, 900, 1100, 1600 may be used for continued processing. In the below example, integrated circuit structure 1400 is illustrated for the sake of clarity of presentation; however, any may be deployed.

Returning to FIG. 1, processing continues at operation 106, where one of the transistor structures is selectively exposed using self-aligned pinhole-based patterning and the sacrificial gate material of the selectively exposed transistor structure is removed. In some embodiments, a patterned hardmask material is formed over selected transistor structure such that an opening in the patterned hardmask material is over at least a region of the selected transistor structure while the other transistor structures are completely covered. In some embodiments, the patterned hardmask material includes an amorphous silicon layer directly on the sacrificial gate material and a carbon hardmask layer is on the amorphous silicon layer. However, any suitable material systems may be used. The pertinent sacrificial gate material of the selectively exposed voltage transistor structure is then removed using any suitable technique or techniques such as wet etch techniques.

Notably, due to the presence of the dielectric or pixel walls fabricated at operations 104, 105, any lateral EPE does not impact the process flow so long as the opening is at least partially over the sacrificial gate material to be removed, and within the dielectric wall. Furthermore, any vertical edge fidelity issues are resolved due to the presence of the dielectric wall. As discussed, in the following, any sacrificial gate material inclusive of reflowable materials may be used.

FIG. 17 is a cross-sectional side view of an example integrated circuit structure 1700 similar to integrated circuit structure 1400, after formation of patterned mask 1703. Patterned mask 1703 may include any number of layers such as first layer 1701 (e.g., an amorphous silicon layer) and a second layer 1702 (e.g., a carbon hardmask layer). Patterned mask 1703 may be formed using any suitable technique or techniques such as bulk deposition of first layer 1701 and second layer 1702 followed by patterning first layer 1701 and second layer 1702 using a patterned resist layer (not shown), which may be subsequently removed.

As shown, an opening 1704 of patterned mask 1703 exposes portions of one transistor structure (i.e., P-HVT) between dielectric wall 302 and a laterally adjacent dielectric wall (not labeled) while the portions of other transistor structures are covered. Thereby, a particular one of the transistor structures may be selectively exposed and processed while other transistor structures are not exposed and processed. As shown, in some embodiments, sacrificial gate material 501 of the exposed transistor structure is selectively removed using any suitable technique or techniques such as wet etch techniques.

As discussed, dielectric walls 301, 302, 303 provide process latitude with respect to EPE such that opening 1704 of patterned mask 1703 may be misaligned away from a centerline of the selected transistor structure such that, irrespective of expected process tolerance EPE, opening 1704 of patterned mask 1703 always lands either within and between dielectric wall 302 and the laterally adjacent dielectric wall or even partially overlapping one of dielectric wall 302 or the laterally adjacent dielectric wall. It is noted that, absent dielectric walls 301, 302, 303, such EPE provides VT shifts, and other process issues. Furthermore, the presence of dielectric walls 301, 302, 303 provides a material interface that ensures vertical fidelity, transistor structure isolation, and other advantages.

Returning to FIG. 1, processing continues at operation 107, where the exposed transistor structure may be selectively processed using any suitable technique or techniques. For example, relative to the obscured transistor structures, the exposed transistor structure may be advantageously processed to selectively apply gate dielectric or dipole materials, work function metals, or the like. Such selective processing includes, but is not limited to, differences in gate dielectric or dipole materials, differences in work function metals, differences in material thicknesses, and selective doping. Thereby, the current techniques provide process flexibility in fabrication of transistor structures while improving patterning fidelity, process window, and transistor structures.

FIG. 18 is a cross-sectional side view of an example integrated circuit structure 1800 similar to integrated circuit structure 1700, during selective processing 1801. As discussed, selective processing 1801 may be any suitable processing such as application of gate dielectric or dipole materials, application of work function metals, selective doping, and so on.

Returning to FIG. 1, as shown with respect to process loop 108, operations 106, 107 may be repeated any number of times for different transistor structures (i.e., P-LVT, P-SVT, P-HVT, N-LVT, N-SVT, N-HVT, or others). With reference to FIG. 18, after selective processing 1801, a sacrificial fill material may be used to embed the components of any prior processed transistor structure, a second or subsequent patterned mask may be used to expose any other structure and the pertinent portion of sacrificial gate material 501 may be removed using, for example, wet etch techniques. Subsequently, the now exposed transistor structure may then be selectively processed to provide any suitable gate dielectric or dipole materials, differences in work function metals, differences in material thicknesses, and selective doping, and so on.

Processing continues at operation 109, where, after selective processing of the transistor structures, any shared processing of the gate structure components is performed. Such processing may include forming bulk gate materials, for example. Such processing may be performed by patterning, exposing transistor structure components, material deposition, and planarization, or other similar processes in analogy to those discussed with respect to operations 106, 107.

FIG. 19 is a cross-sectional side view of an example integrated circuit structure 1900 similar to integrated circuit structure 1800, after selective processing of each transistor structure. As shown, one of the transistor structures (P-LVT) includes one or more of a gate dielectric, gate dipole material, or gate work function material layer 1902 on each of channel material layers 204. As shown, material layer 1902 is also on a sidewall or surface of dielectric wall 301 and the other dielectric wall bounding transistor structures (P-LVT). In the context of integrated circuit structure 1900, material layer 1902 as well as material layers 1905 and similar material layers are illustrated as a single layer, but may include a bilayer, trilayer, or the like depending on the architecture of integrated circuit structure 1900. The transistor structure (P-LVT) includes a gate electrode 1903 on material layer 1902, and material layer 1902 and gate electrode 1903 may be characterized as a gate stack or gate structure 1901.

Other ones of the transistor structures may include the same or different material layers and structures depending on the selective or shared processing provided using the above techniques. For example, the transistor structure (N-LVT) further includes a gate dielectric, gate dipole material, or gate work function material layer 1905 on each of the channel material layers thereof, and a gate electrode 1906 on material layer 1905. Material layer 1905 is also on sidewall or surface of dielectric wall 302 and sidewall or surface of the adjacent dielectric wall containing the transistor structure (N-LVT). Material layer 1905 and gate electrode 1906 may be characterized as a gate stack or gate structure 1904. Using the discussed techniques, a variety of combinations of gate dielectric, gate dipole material, or gate work function material layers and gate electrodes are available for each transistor structure of integrated circuit structure 1900. Any of such layers or structures may be the same or different across integrated circuit structure 1900 based on the discussed selective processing and separation using dielectric walls 301, 302, 303.

Returning to FIG. 1, processing continues at operation 110, where frontside contacts, frontside metallization, and optional backside metallization are formed, and the resultant device is output. For example, any or all of the discussed source structures, drain structures, and gate structures the transistor structures may be contacted by frontside metal contacts using any suitable technique or techniques such as patterning and metal deposition processing as is known in the art. The frontside contacts are then interconnected by metallization layers over the frontside contact. Backside metallization is optionally fabricated opposite the frontside metallization with respect to a device layer including the discussed integrated circuit structures. In some embodiments, the frontside metallization provides signal routing and the backside metallization to provides power delivery. However, any interconnect routing may be used. Additional fabrication processes may then be completed, and the resultant structure may be output. Such processing may include backend processing, dicing, packaging, assembly, and so on. The resultant device (e.g., integrated circuit die) may then be implemented in any suitable form factor device such as a laptop, a netbook, a notebook, an ultrabook, a smartphone, a tablet, a personal digital assistant, an ultra-mobile PC, a mobile phone, a desktop computer, a server, a printer, a scanner, a monitor, a set-top box, an entertainment control unit, a digital camera, a portable music player, a digital video recorder, or the like.

FIG. 20 is a cross-sectional side view of a multi-layer integrated circuit device structure 2000 incorporating integrated circuit structure 1900, arranged in accordance with at least some embodiments of the present disclosure. Although illustrated and discussed with respect to integrated circuit structure 1900, any integrated circuit structures discussed herein may be deployed in the context of multi-layer integrated circuit device structure 2000. As shown, multi-layer integrated circuit device structure 2000 is incorporated in integrated circuit (IC) die 2007 such that multi-layer integrated circuit device structure 2000 includes frontside metallization layers 2001 (or frontside interconnect layers) and backside metallization layers 2002 (or backside interconnect layers). Frontside metallization layers 2001 and backside metallization layers 2002 may be formed using any suitable technique or techniques such as dual damascene techniques, single damascene techniques, subtractive metallization patterning techniques, or the like. In some embodiments, backside metallization layers 2002 are not deployed.

In some embodiments, interconnectivity, signal routing, power-delivery, and the like may be provided by frontside metallization layers 2001. Adjacent metallization layers, such as metallization interconnects 2009 are interconnected by vias, such as vias 2003, that may be characterized as part of the metallization layers or between the metallization layers. As shown, in some embodiments, frontside metallization layers 2001 are formed over and immediately adjacent integrated circuit structure 1900. In the illustrated example, frontside metallization layers 2001 include M0, V0, M1, M2/V1, M3/V2, and M4/V3. However, frontside metallization layers 2001 may include any number of metallization layers such as six, eight, or more metallization layers.

Similarly, backside metallization layers 2002, may be used for interconnectivity, signal routing, power-delivery, and any other suitable electrical connectivity. In some embodiments, frontside metallization layers 2001 are used exclusively for signal routing and backside metallization layers 2002 are used exclusively for power delivery. However, any interconnection architecture may be used. In the illustrated example, package level interconnects 2008 are provided on or over a device backside as bumps over a passivation layer 2005. However, package level interconnects 2008 may be provided using any suitable interconnect structures such as bond pads, solder bumps, etc. As shown, in some embodiments, backside metallization layers 2002 are formed over and immediately adjacent integrated circuit structure 1900 such that a device layer 2004 including integrated circuit structure 1900 is between frontside metallization layers 2001 and backside metallization layers 2002. In the illustrated example, backside metallization layers 2002 include BM0, BM1, and BM2 with intervening via layers. However, backside metallization layers 2002 may include any number of metallization layers such as three, four, or more metallization layers.

In some embodiments, an integrated circuit structure including integrated circuit structure 1900 is deployed in a monolithic integrated circuit (IC) die 2007 including gate-all-around field effect transistor structures (e.g., GAA-FETs) including any of the discussed components and characteristics. As shown, a power supply 2006 may be coupled to IC die 2007, such that power supply 2006 may include a battery, voltage converter, power supply circuitry, or the like.

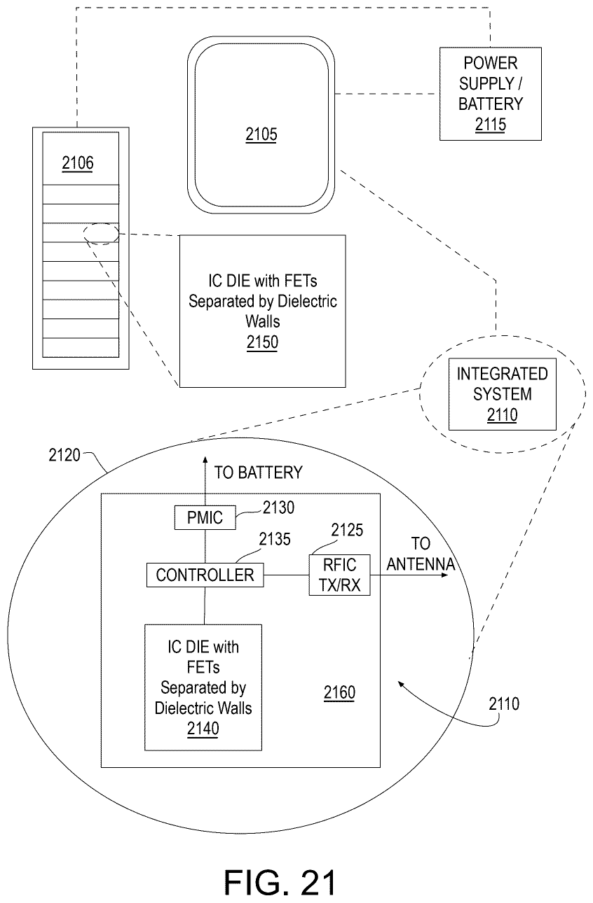

FIG. 21 illustrates exemplary systems employing integrated circuit structures with transistor structures separated by dielectric walls, in accordance with some embodiments. The system may be a mobile computing platform 2105 and/or a data server machine 2106, for example. Either may employ a component assembly including an IC die having integrated circuit structures with transistor structures separated by dielectric walls as described elsewhere herein. Server machine 2106 may be any commercial server, for example including any number of high-performance computing platforms disposed within a rack and networked together for electronic data processing, which in the exemplary embodiment includes an IC die assembly 2150 with an IC die employing integrated circuit structures with integrated circuit structures having transistor structures separated by dielectric walls as described elsewhere herein. Mobile computing platform 2105 may be any portable device configured for each of electronic data display, electronic data processing, wireless electronic data transmission, or the like. For example, mobile computing platform 2105 may be any of a tablet, a smart phone, a laptop computer, etc., and may include a display screen (e.g., a capacitive, inductive, resistive, or optical touchscreen), a chip-level or package-level integrated system 2110, and a battery 2115. Although illustrated with respect to mobile computing platform 2105, in other examples, chip-level or package-level integrated system 2110 and a battery 2115 may be implemented in a desktop computing platform, an automotive computing platform, an internet of things platform, or the like. As discussed below, in some examples, the disclosed systems may include a sub-system 2160 such as a system on a chip (SOC) or an integrated system of multiple ICs, which is illustrated with respect to mobile computing platform 2105.

Whether disposed within integrated system 2110 illustrated in expanded view 2120 or as a stand-alone packaged device within data server machine 2106, sub-system 2160 may include memory circuitry and/or processor circuitry 2140 (e.g., RAM, a microprocessor, a multi-core microprocessor, graphics processor, etc.), a power management integrated circuit (PMIC) 2130, a controller 2135, and a radio frequency integrated circuit (RFIC) 2125 (e.g., including a wideband RF transmitter and/or receiver (TX/RX)). As shown, one or more IC dies, such as memory circuitry and/or processor circuitry 2140 may be fabricated and implemented such that one or more have an IC die employing integrated circuit structures with transistor structures separated by dielectric walls as described herein. In some embodiments, RFIC 2125 includes a digital baseband and an analog front-end module further comprising a power amplifier on a transmit path and a low noise amplifier on a receive path). Functionally, PMIC 2130 may perform battery power regulation, DC-to-DC conversion, etc., and so has an input coupled to battery 2115, and an output providing a current supply to other functional modules. As further illustrated in FIG. 21, in the exemplary embodiment, RFIC 2125 has an output coupled to an antenna (not shown) to implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. Memory circuitry and/or processor circuitry 2140 may provide memory functionality for sub-system 2160, high level control, data processing and the like for sub-system 2160. In alternative implementations, each of the SOC modules may be integrated onto separate ICs coupled to a package substrate, interposer, or board.

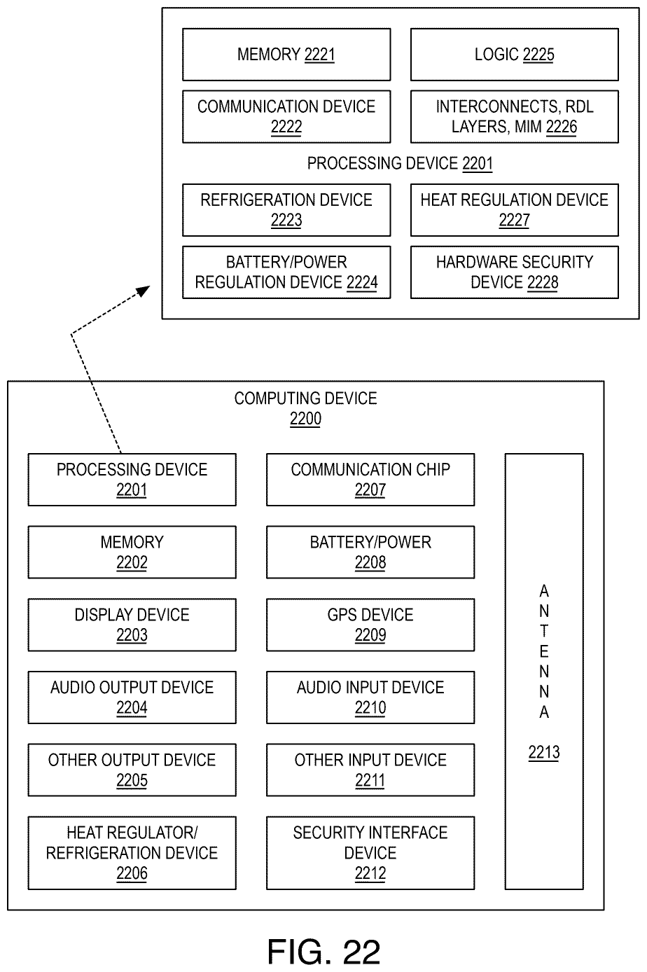

FIG. 22 is a block diagram of a computing device 2200, in accordance with some embodiments. For example, one or more components of computing device 2200 may include any of the integrated circuit structures with transistor structures separated by dielectric walls as discussed elsewhere herein. A number of components are illustrated in FIG. 22, but any one or more of these components may be omitted or duplicated, as suitable for the application. In some embodiments, some of the components included in computing device 2200 may be attached to one or more printed circuit boards (e.g., a motherboard). In some embodiments, various ones of these components may be fabricated onto a single system-on-a-chip (SoC) die or implemented with a disintegrated plurality of chiplets or tiles packaged together. Any of such packaged components may include integrated circuit structures with transistor structures separated by dielectric walls as discussed herein. Additionally, in various embodiments, computing device 2200 may not include one or more of the components illustrated in FIG. 22, but computing device 2200 may include interface circuitry for coupling to the one or more components. For example, computing device 2200 may not include a display device 2203, but may include display device interface circuitry (e.g., a connector and driver circuitry) to which display device 2203 may be coupled.

Computing device 2200 may include a processing device 2201 (e.g., one or more processing devices). As used herein, the term processing device or processor indicates a device that processes electronic data from registers and/or memory to transform that electronic data into other electronic data that may be stored in registers and/or memory. Processing device 2201 may include a memory 2221, a communication device 2222, a refrigeration/active cooling device 2223, a battery/power regulation device 2224, logic 2225, interconnects 2226, a heat regulation device 2227, and a hardware security device 2228.

Processing device 2201 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable compute units.

Processing device 2201 may include a memory 2202, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, processing device 2201 shares a package with memory 2202. This memory may be used as cache memory and may include embedded dynamic random-access memory (eDRAM) or spin transfer torque magnetic random-access memory (STT-M RAM).

Computing device 2200 may include a heat regulation/refrigeration device 2206. Heat regulation/refrigeration device 2206 may maintain processing device 2201 (and/or other components of computing device 2200) at a predetermined low temperature during operation. This predetermined low temperature may be any temperature discussed elsewhere herein.

In some embodiments, computing device 2200 may include a communication chip 2207 (e.g., one or more communication chips). For example, the communication chip 2207 may be configured for managing wireless communications for the transfer of data to and from computing device 2200. The term “wireless” and its derivatives may be used to describe circuits, devices, systems, methods, techniques, communications channels, etc., that may communicate data through the use of modulated electromagnetic radiation through a nonsolid medium.

Computing device 2200 may include any photonics structure discussed herein that may facilitate communication between one or more instances of processing device 2201 and/or one or more instances of memory 2202, for example.

Computing device 2200 may include battery/power circuitry 2208. Battery/power circuitry 2208 may include one or more energy storage devices (e.g., batteries or capacitors) and/or circuitry for coupling components of computing device 2200 to an energy source separate from computing device 2200 (e.g., AC line power).

Computing device 2200 may include a display device 2203 (or corresponding interface circuitry, as discussed above). Display device 2203 may include any visual indicators, such as a heads-up display, a computer monitor, a projector, a touchscreen display, a liquid crystal display (LCD), a light-emitting diode display, or a flat panel display, for example.

Computing device 2200 may include an audio output device 2204 (or corresponding interface circuitry, as discussed above). Audio output device 2204 may include any device that generates an audible indicator, such as speakers, headsets, or earbuds, for example.

Computing device 2200 may include an audio input device 2210 (or corresponding interface circuitry, as discussed above). Audio input device 2210 may include any device that generates a signal representative of a sound, such as microphones, microphone arrays, or digital instruments (e.g., instruments having a musical instrument digital interface (MIDI) output).

Computing device 2200 may include a global positioning system (GPS) device 2209 (or corresponding interface circuitry, as discussed above). GPS device 2209 may be in communication with a satellite-based system and may receive a location of computing device 2200, as known in the art.

Computing device 2200 may include another output device 2205 (or corresponding interface circuitry, as discussed above). Examples include an audio codec, a video codec, a printer, a wired or wireless transmitter for providing information to other devices, or an additional storage device.

Computing device 2200 may include another input device 2211 (or corresponding interface circuitry, as discussed above). Examples may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2200 may include a security interface device 2212. Security interface device 2212 may include any device that provides security measures for computing device 2200 such as intrusion detection, biometric validation, security encode or decode, managing access lists, malware detection, or spyware detection.

Computing device 2200 may include an antenna 2213. Antenna 2213 may include any device that translates electrical current to radio waves and/or translates radio waves to electrical current.

Computing device 2200, or a subset of its components, may have any appropriate form factor, such as a server or other networked computing component, a mobile device, a printer, a scanner, a monitor, a set-top box, an entertainment control unit, a vehicle control unit, a digital camera, a digital video recorder, or a wearable computing device.

While certain features set forth herein have been described with reference to various implementations, this description is not intended to be construed in a limiting sense. Hence, various modifications of the implementations described herein, as well as other implementations, which are apparent to persons skilled in the art to which the present disclosure pertains are deemed to lie within the spirit and scope of the present disclosure.

It will be recognized that the invention is not limited to the embodiments so described, but can be practiced with modification and alteration without departing from the scope of the appended claims. For example, the above embodiments may include specific combinations of features as further provided below.

The following pertain to exemplary embodiments.

In one or more first embodiments, an apparatus comprises a first transistor structure comprising a first stack of channel material layers and a first gate structure coupled to the first stack of channel material layers, a second transistor structure comprising a second stack of channel material layers and a second gate structure coupled to the second stack of channel material layers, and a dielectric wall between the first transistor structure and the second transistor structure, the dielectric wall comprising a fill dielectric material within a dielectric liner, wherein the first gate structure is on a first surface of the dielectric liner and the second gate structure is on a second surface of the dielectric liner opposite the fill dielectric material from the first surface.

In one or more second embodiments, further to the first embodiments, the dielectric liner comprises silicon and one of nitrogen or carbon.

In one or more third embodiments, further to the first or second embodiments, the fill dielectric material comprises silicon and oxygen.

In one or more fourth embodiments, further to the first through third embodiments, the dielectric wall further comprises a dielectric cap on a top surface of the fill dielectric material and laterally adjacent to a portion of the first gate structure and a portion of the second gate structure.

In one or more fifth embodiments, further to the first through fourth embodiments, the dielectric cap comprises silicon and one of nitrogen or carbon.

In one or more sixth embodiments, further to the first through fifth embodiments, the dielectric liner comprises silicon and one of nitrogen or carbon, the fill dielectric material comprises silicon and oxygen, and the dielectric cap comprises silicon and one of nitrogen or carbon.

In one or more seventh embodiments, further to the first through sixth embodiments, the first transistor structure comprises a first conductivity type and the second transistor structure comprises a second conductivity type, and the apparatus further comprises a third transistor structure comprising a third stack of channel material layers and a third gate structure coupled to the third stack of channel material layers, wherein the third transistor structure comprises the first conductivity type, and a second dielectric wall between the first transistor structure and the third transistor structure, the second dielectric wall comprising a second fill dielectric material within a second dielectric liner, wherein the first gate structure is on a first surface of the second dielectric liner and the third gate structure is on a second surface of the second dielectric liner opposite the second fill dielectric material from the first surface of the second dielectric liner.

In one or more eighth embodiments, further to the first through seventh embodiments, the apparatus further comprises a power supply, and an integrated circuit device coupled to the power supply, the integrated circuit device comprising the first transistor structure, the second transistor structure, and the dielectric wall.

In one or more ninth embodiments, a system comprises an IC die according to any of the apparatuses of the first through eighth embodiments, the system further including a power supply or a display coupled to the first or second transistor structure.

In one or more tenth embodiments, an apparatus comprises a first transistor structure comprising a first stack of channel material layers and a first gate structure coupled to at least the first stack of channel material layers, a second transistor structure comprising a second stack of channel material layers and a second gate structure coupled to at least the second stack of channel material layers, and a dielectric wall between the first transistor structure and the second transistor structure, the dielectric wall comprising a first dielectric portion laterally aligned with at least some of the first stack of channel material layers and a dielectric cap on the first dielectric portion, wherein the first gate structure is on a first surface defined by the first dielectric portion and the dielectric cap and the second gate structure is on a second surface defined by the first dielectric portion and the dielectric cap opposite the first surface.

In one or more eleventh embodiments, further to the tenth embodiments, the dielectric wall further comprises a seam within the first dielectric portion between the first gate structure and the second gate structure, wherein the dielectric cap buries the seam within an interior of the dielectric wall.

In one or more twelfth embodiments, further to the tenth or eleventh embodiments, the first dielectric portion comprises silicon and one of oxygen or nitrogen.

In one or more thirteenth embodiments, further to the tenth through twelfth embodiments, the dielectric cap comprises silicon and one of carbon or nitrogen.

In one or more fourteenth embodiments, further to the tenth through thirteenth embodiments, the first dielectric portion comprises a dielectric fill material within a dielectric liner, the dielectric fill material comprising silicon and oxygen and the dielectric liner comprising silicon and one of carbon or nitrogen.

In one or more fifteenth embodiments, further to the tenth through fourteenth embodiments, the first transistor structure comprises a first conductivity type and the second transistor structure comprises a second conductivity type, and the apparatus further comprises a third transistor structure comprising a third stack of channel material layers and a third gate structure coupled to the third stack of channel material layers, wherein the third transistor structure comprises the first conductivity type, and a second dielectric wall between the first transistor structure and the third transistor structure, the second dielectric wall comprising a second dielectric portion laterally aligned with at least some of the first stack of channel material layers and a second dielectric cap on the second dielectric portion, wherein first gate structure is on a third surface defined by the second dielectric portion and the second dielectric cap and the third gate structure is on a fourth surface defined by the second dielectric portion and the second dielectric cap opposite the third surface.

In one or more sixteenth embodiments, further to the tenth through fifteenth embodiments, the apparatus further comprises a power supply, and an integrated circuit device coupled to the power supply, the integrated circuit device comprising the first transistor structure, the second transistor structure, and the dielectric wall.

In one or more seventeenth embodiments, a system comprises an IC die according to any of the apparatuses of the tenth through sixteenth embodiments, the system further including a power supply or a display coupled to the first or second transistor structure.

In one or more eighteenth embodiments, a method comprises embedding a first stack of channel material layers and a laterally adjacent second stack of channel material layers in a reflowable material, forming a dielectric wall in the reflowable material and between the first stack of channel material layers and the second stack of channel material layers, selectively removing a first portion of the reflowable material to expose the first stack of channel material layers, and forming at least portion of a first gate structure on the first stack of channel material layers.

In one or more nineteenth embodiments, further to the eighteenth embodiments, the reflowable material comprises one of amorphous carbon film, an amorphous silicon film, a silicon oxide film, a silicon oxycarbide, or an aluminum oxide film.

In one or more twentieth embodiments, further to the eighteenth or nineteenth embodiments, forming the dielectric wall comprises forming a fill material within a liner layer.

In one or more twenty-first embodiments, further to the eighteenth through twentieth embodiments, forming the dielectric wall comprises recessing a first dielectric portion and forming a dielectric cap on the first dielectric portion.

In one or more twenty-second embodiments, further to the eighteenth through twenty-first embodiments, selectively removing a first portion of the reflowable material to expose the first stack of channel material layers comprises forming a mask comprising an opening over the first stack of channel material layers, the mask covering the second stack of channel material layers.

It will be recognized that the invention is not limited to the embodiments so described, but can be practiced with modification and alteration without departing from the scope of the appended claims. For example, the above embodiments may include specific combination of features. However, the above embodiments are not limited in this regard and, in various implementations, the above embodiments may include undertaking only a subset of such features, undertaking a different order of such features, undertaking a different combination of such features, and/or undertaking additional features than those features explicitly listed. The scope of the invention should, therefore, be determined with reference to the appended claims, along with the full scope of equivalents to which such claims are entitled.

What is claimed is:

1. An apparatus, comprising:
a first transistor structure comprising a first stack of channel material layers and a first gate structure coupled to the first stack of channel material layers;
a second transistor structure comprising a second stack of channel material layers and a second gate structure coupled to the second stack of channel material layers; and
a dielectric wall between the first transistor structure and the second transistor structure, the dielectric wall comprising a fill dielectric material within a dielectric liner, wherein the first gate structure is on a first surface of the dielectric liner and the second gate structure is on a second surface of the dielectric liner opposite the fill dielectric material from the first surface.

2. The apparatus of claim 1, wherein the dielectric liner comprises silicon and one of nitrogen or carbon.

3. The apparatus of claim 2, wherein the fill dielectric material comprises silicon and oxygen.

4. The apparatus of claim 1, wherein the dielectric wall further comprises a dielectric cap on a top surface of the fill dielectric material and laterally adjacent to a portion of the first gate structure and a portion of the second gate structure.

5. The apparatus of claim 4, wherein the dielectric cap comprises silicon and one of nitrogen or carbon.

6. The apparatus of claim 4, wherein the dielectric liner comprises silicon and one of nitrogen or carbon, the fill dielectric material comprises silicon and oxygen, and the dielectric cap comprises silicon and one of nitrogen or carbon.

7. The apparatus of claim 1, wherein the first transistor structure comprises a first conductivity type and the second transistor structure comprises a second conductivity type, the apparatus further comprising:
a third transistor structure comprising a third stack of channel material layers and a third gate structure coupled to the third stack of channel material layers, wherein the third transistor structure comprises the first conductivity type; and
a second dielectric wall between the first transistor structure and the third transistor structure, the second dielectric wall comprising a second fill dielectric material within a second dielectric liner, wherein the first gate structure is on a first surface of the second dielectric liner and the third gate structure is on a second surface of the second dielectric liner opposite the second fill dielectric material from the first surface of the second dielectric liner.

8. The apparatus of claim 1, further comprising:
a power supply; and
an integrated circuit device coupled to the power supply, the integrated circuit device comprising the first transistor structure, the second transistor structure, and the dielectric wall.

9. An apparatus, comprising:
a first transistor structure comprising a first stack of channel material layers and a first gate structure coupled to at least the first stack of channel material layers;
a second transistor structure comprising a second stack of channel material layers and a second gate structure coupled to at least the second stack of channel material layers; and
a dielectric wall between the first transistor structure and the second transistor structure, the dielectric wall comprising a first dielectric portion laterally aligned with at least some of the first stack of channel material layers and a dielectric cap on the first dielectric portion, wherein the first gate structure is on a first surface defined by the first dielectric portion and the dielectric cap and the second gate structure is on a second surface defined by the first dielectric portion and the dielectric cap opposite the first surface.

10. The apparatus of claim 9, wherein the dielectric wall further comprises a seam within the first dielectric portion between the first gate structure and the second gate structure, wherein the dielectric cap buries the seam within an interior of the dielectric wall.

11. The apparatus of claim 9, wherein the first dielectric portion comprises silicon and one of oxygen or nitrogen.

12. The apparatus of claim 9, wherein the dielectric cap comprises silicon and one of carbon or nitrogen.

13. The apparatus of claim 9, wherein the first dielectric portion comprises a dielectric fill material within a dielectric liner, the dielectric fill material comprising silicon and oxygen and the dielectric liner comprising silicon and one of carbon or nitrogen.

14. The apparatus of claim 9, wherein the first transistor structure comprises a first conductivity type and the second transistor structure comprises a second conductivity type, the apparatus further comprising:
a third transistor structure comprising a third stack of channel material layers and a third gate structure coupled to the third stack of channel material layers, wherein the third transistor structure comprises the first conductivity type; and
a second dielectric wall between the first transistor structure and the third transistor structure, the second dielectric wall comprising a second dielectric portion laterally aligned with at least some of the first stack of channel material layers and a second dielectric cap on the second dielectric portion, wherein first gate structure is on a third surface defined by the second dielectric portion and the second dielectric cap and the third gate structure is on a fourth surface defined by the second dielectric portion and the second dielectric cap opposite the third surface.

15. The apparatus of claim 9, further comprising:
a power supply; and
an integrated circuit device coupled to the power supply, the integrated circuit device comprising the first transistor structure, the second transistor structure, and the dielectric wall.

16. A method, comprising:
embedding a first stack of channel material layers and a laterally adjacent second stack of channel material layers in a reflowable material;
forming a dielectric wall in the reflowable material and between the first stack of channel material layers and the second stack of channel material layers;
selectively removing a first portion of the reflowable material to expose the first stack of channel material layers; and
forming at least portion of a first gate structure on the first stack of channel material layers.

17. The method of claim 16, wherein the reflowable material comprises one of amorphous carbon film, an amorphous silicon film, a silicon oxide film, a silicon oxycarbide, or an aluminum oxide film.

18. The method of claim 16, wherein forming the dielectric wall comprises forming a fill material within a liner layer.

19. The method of claim 16, wherein forming the dielectric wall comprises recessing a first dielectric portion and forming a dielectric cap on the first dielectric portion.

20. The method of claim 16, wherein selectively removing a first portion of the reflowable material to expose the first stack of channel material layers comprises:
forming a mask comprising an opening over the first stack of channel material layers, the mask covering the second stack of channel material layers.
